(19) United States
(12) Patent Application Publication
(10) Pub. No.: US 2026/0026296 A1
(43) Pub. Date: Jan. 22, 2026

(54) AUTOMATIC CREATION OF AN IMAGING RECIPE

(71) Applicant: Applied Materials Israel Ltd., Rehovot (IL)

(72) Inventors: Vadim KUCHIK, Kiriat Ekron (IL); Yaniv ABRAMOVITZ, Mazkeret Batya (IL); Dan Tuvia FUCHS, Tel-Aviv (IL); Itay ASULIN, Rehovot (IL)

(21) Appl. No.: 18/780,401

(22) Filed: Jul. 22, 2024

(51) Int. Cl. H01L 21/67; G06F 30/30; G06T 7/00

(52) U.S. Cl. CPC H01L 21/67288; G06F 30/30; G06T 7/0004; G06T 2207/10061; G06T 2207/30148

(57) ABSTRACT

A system and method for automatic optimization of an imaging recipe of an electron beam tool are provided. The method includes obtaining material and structural properties of a semiconductor specimen of interest (SOI); performing a first simulation of the interaction between irradiated electrons of a primary beam and the SOI at various primary beam configurations to obtain maps of escaped electron distribution in terms of polar angle and escape energy; performing, based on the maps, a second simulation of the collection and detection of escaped electrons at different imaging configurations to obtain a signal profile of a measurement of interest (MOI) on the SOI at each imaging configuration; and creating an imaging recipe for the electron beam tool, comprising primary beam parameters and tool imaging parameters configured to achieve optimal contrast of the MOI in the signal profile.

### TECHNICAL FIELD

The presently disclosed subject matter relates, in general, to the field of examination of a semiconductor specimen, and more specifically, to automatic creation of an imaging recipe for imaging a semiconductor specimen.

### BACKGROUND

Current demands for high density and performance associated with ultra large-scale integration of fabricated devices require submicron features, increased transistor and circuit speeds, and improved reliability. As semiconductor processes progress, pattern dimensions such as line width, and other types of critical dimensions, are continuously shrunken. Such demands require formation of device features with high precision and uniformity, which, in turn, necessitates careful monitoring of the fabrication process, including automated examination of the devices while they are still in the form of semiconductor wafers.

Examination can be provided by using non-destructive examination tools during or after manufacture of the specimen to be examined. A variety of non-destructive examination tools includes, by way of non-limiting example, scanning electron microscopes, atomic force microscopes, optical inspection tools, etc.

Examination processes can include a plurality of examination steps. The manufacturing process of a semiconductor device can include various procedures such as etching, depositing, planarization, growth such as epitaxial growth, implantation, etc. The examination steps can be performed a multiplicity of times, for example after certain process procedures, and/or after the manufacturing of certain layers, or the like. Additionally, or alternatively, each examination step can be repeated multiple times, for example for different wafer locations, or for the same wafer locations with different examination settings.

During the examination processes at various steps during semiconductor fabrication, examination images are acquired by the examination tools which are processed for purpose of examination operations such as detecting and classifying defects on specimens, as well as performing metrology related operations.

Effectiveness of examination can be improved by automatization of process(es) such as, for example, defect detection, Automatic Defect Classification (ADC), Automatic Defect Review (ADR), image segmentation, automated metrology-related operations, etc. Automated examination systems ensure that the parts manufactured meet the quality standards expected and provide useful information on adjustments that may be needed to the manufacturing tools, equipment, and/or compositions, depending on the type of defects identified.

### SUMMARY

In accordance with certain aspects of the presently disclosed subject matter, there is provided a computerized system of automatic creation of an imaging recipe of an electron beam tool, the system comprising a processing circuitry configured to obtain, as input, material properties and structural properties of a semiconductor specimen of interest (SOI); perform, based on the input, a first simulation representative of interaction between irradiated electrons of a primary beam of the electron beam tool and the SOI at a plurality of primary beam configurations characterized by different values of a set of primary beam parameters, to obtain, for each primary beam configuration, a map representative of distribution of escaped electrons in terms of polar angle and escape energy; perform, based on the map, a second simulation representative of collection and detection of the escaped electrons at different tool imaging configurations characterized by different values of a set of tool imaging parameters, to obtain a signal profile of a measurement of interest (MOI) on the SOI at each tool imaging configuration; and create an imaging recipe for the electron beam tool, comprising the set of primary beam parameters and the set of tool imaging parameters configured with values that result in an optimal contrast of the MOI in the signal profile.

In addition to the above features, the system according to this aspect of the presently disclosed subject matter can comprise one or more of features (i) to (x) listed below, in any desired combination or permutation which is technically possible:
(i). The material properties comprise one or more of: composition, density, and stoichiometric formula of materials constituting the specimen. The structural properties comprise one or more of: layer layout, thickness, and geometric dimensions of structural features on each layer.
(ii). The set of primary beam parameters comprises one or more of: landing energy, beam resolution, current amplitude, current density, electron source, and numerical aperture (NA) of the electron beam tool.
(iii). The set of tool imaging parameters comprises one or more of: detector angle, detector gain, defector offset, electrostatic field, voltage, mechanical configuration, dwell time, scanning speed, pixel size, and energy filter of the electron beam tool. The signal profile is represented in a multi-dimensional parameter space.
(iv). The processing circuitry is configured to perform the second simulation by simulating a signal detected by a given detector based on a correlation between detector gain, energy, and current of incoming electrons of the given detector.
(v). The imaging recipe is a wafer-less recipe which is created without acquiring an actual SOI, thereby enabling improved time-to-recipe.
(vi). The SOI is Vertical NAND (V-NAND), the MOI represents an overlay measurement between two consecutive layers, and the imaging recipe comprises at least a landing energy configured within a selected range, and a side detector positioned at a polar angle within a selected range.
(vii). The imaging recipe further comprises the side detector configured with a selected detector gain, and at least one energy filter configured to filter out escaped electrons with unwanted energy levels.
(viii). The simulation data of the first simulation and the second simulation is usable to design a new e-beam tool with tool parameters configured with selected values proven to result in an optimal contrast of the MOI.
(ix). The simulation data of the first simulation and the second simulation is usable for providing feedback to manufacturers with respect to optimizing material properties and/or structural properties of future specimens of interests (SOIs) to be manufactured for enhancing an electron beam examination process.
(x). The electron beam tool is one of: a defect inspection tool, a defect review tool, or a metrology tool.

In accordance with other aspects of the presently disclosed subject matter, there is provided a computerized method of automatic creation of an imaging recipe of an electron beam tool, the method comprising: obtaining, as input, material properties and structural properties of a semiconductor specimen of interest (SOI); performing, based on the input, a first simulation representative of interaction between irradiated electrons of a primary beam of the electron beam tool and the SOI at a plurality of primary beam configurations characterized by different values of a set of primary beam parameters, to obtain, for each primary beam configuration, a map representative of distribution of escaped electrons in terms of polar angle and escape energy; performing, based on the map, a second simulation representative of collection and detection of the escaped electrons at different tool imaging configurations characterized by different values of a set of tool imaging parameters, to obtain a signal profile of a measurement of interest (MOI) on the SOI at each tool imaging configuration; and creating an imaging recipe for the electron beam tool, comprising the set of primary beam parameters and the set of tool imaging parameters configured with values that result in an optimal contrast of the MOI in the signal profile.

These aspects of the disclosed subject matter can comprise one or more of features (i) to (x) listed above with respect to the system, mutatis mutandis, in any desired combination or permutation which is technically possible.

In accordance with other aspects of the presently disclosed subject matter, there is provided a non-transitory computer readable medium comprising instructions that, when executed by a computer, cause the computer to perform a method of automatic creation of an imaging recipe of an electron beam tool, the method comprising: obtaining, as input, material properties and structural properties of a semiconductor specimen of interest (SOI); performing, based on the input, a first simulation representative of interaction between irradiated electrons of a primary beam of the electron beam tool and the SOI at a plurality of primary beam configurations characterized by different values of a set of primary beam parameters, to obtain, for each primary beam configuration, a map representative of distribution of escaped electrons in terms of polar angle and escape energy; performing, based on the map, a second simulation representative of collection and detection of the escaped electrons at different tool imaging configurations characterized by different values of a set of tool imaging parameters, to obtain a signal profile of a measurement of interest (MOI) on the SOI at each tool imaging configuration; and creating an imaging recipe for the electron beam tool, comprising the set of primary beam parameters and the set of tool imaging parameters configured with values that result in an optimal contrast of the MOI in the signal profile.

This aspect of the disclosed subject matter can comprise one or more of features (i) to (x) listed above with respect to the system, mutatis mutandis, in any desired combination or permutation which is technically possible.

### BRIEF DESCRIPTION OF THE DRAWINGS

In order to understand the disclosure and to see how it may be carried out in practice, embodiments will now be described, by way of non-limiting example only, with reference to the accompanying drawings, in which:

FIG. 1 illustrates a generalized block diagram of an examination system in accordance with certain embodiments of the presently disclosed subject matter.

FIG. 2 illustrates a generalized flowchart of automatic recipe creation/optimization in accordance with certain embodiments of the presently disclosed subject matter.

FIG. 3 illustrates a generalized flowchart of using the created imaging recipe in accordance with certain embodiments of the presently disclosed subject matter.

FIG. 4 shows an example of a specimen of interest (SOI) and a MOI on the SOI in accordance with certain embodiments of the presently disclosed subject matter.

FIG. 5 illustrates an example of output data of the first simulation in accordance with certain embodiments of the presently disclosed subject matter.

FIG. 6 illustrates an example of signal profiles resulting from the second simulation in accordance with certain embodiments of the presently disclosed subject matter.

FIG. 7 provides an illustration of detectors and energy filters utilized for optimal imaging of the specimen in accordance with certain embodiments of the presently disclosed subject matter.

FIG. 8 illustrates an example of a correlation relationship between the detector gain, the hitting energy, and the hitting current, in accordance with certain embodiments of the presently disclosed subject matter.

### DETAILED DESCRIPTION OF EMBODIMENTS

The process of semiconductor manufacturing often requires multiple sequential processing steps and/or layers, some of which could possibly cause errors that may lead to yield loss. Examples of various processing steps can include lithography, etching, depositing, planarization, growth (such as, e.g., epitaxial growth), and implantation, etc. Various examination operations, such as defect-related examination (e.g., defect detection, defect review, and defect classification, etc.), and/or metrology-related examination (e.g., critical dimension (CD) measurements, etc.), can be performed at different processing steps/layers during the manufacturing process to monitor and control the process. The examination operations can be performed a multiplicity of times, for example after certain processing steps, and/or after the manufacturing of certain layers, or the like.

As described above, various types of examination tools can be used for performing examination of a semiconductor specimen, such as, e.g., optical inspection tools, electron beam tools, etc. By way of example, scanning electron microscopes (SEM) are a type of electron microscopes that utilizes electron beams to illuminate the surface of a specimen where the electrons interact with atoms in the specimen, generating signals that are then collected and analyzed to produce high-resolution images revealing details about the specimen's structure and composition. An SEM is capable of accurately inspecting and measuring features during the manufacture of semiconductor wafers.

Obtaining high-quality SEM images, such as SEM images with high resolution, and/or high SNR, is essential for accurate examination of a semiconductor specimen. High-quality image acquisition requires careful optimization of various tool parameters, which in combination is known as an “imaging recipe” or “tool imaging recipe” of an examination tool. By way of non-limiting example, such parameters can include, e.g., electron beam energy, beam current, lens settings, detector settings, etc.

Traditionally, the development of imaging recipes for such tools has been a labor-intensive and time-consuming process, heavily reliant on manual experimentation and parameter adjustment. It often involves manual adjustments where a skilled operator invests significant time and effort in tuning a multitude of tool parameters while observing the resulting images from SEM so as to achieve optimal imaging conditions. The recipe tuning is typically a trial-and-error experimentation, which requires repeated adjustments and image acquisition, with limited predictability of success and stability. The recipe development process often relies on the operator's experience and intuition, leading to inconsistent results and difficulty in replicating optimal settings.

Moreover, the conventional approach to refining imaging recipes necessitates the availability of physical wafers for testing purposes. This requirement not only consumes valuable resources, but also imposes limitations on the feasibility of experimentation, particularly when access to wafers is restricted, or when conducting preliminary tests in the early stages of recipe development. In addition, conventional recipe development is typically wafer-dependent, meaning that even in cases where the physical wafer is available, the recipe needs to be optimized for each specific type of wafer. This can be inefficient and time-consuming, especially when dealing with novel materials and/or complex structures.

These limitations can significantly slow down development of effective imaging recipes of examination tools for semiconductor specimen examination.

As semiconductor fabrication processes continue to advance, semiconductor devices are developed with increasingly complex structures with shrinking feature dimensions, which has increased the necessity of developing an automatic approach for imaging recipe generation and optimization for semiconductor examination tools.

Accordingly, certain embodiments of the presently disclosed subject matter propose an automatic recipe generation and/or optimization system, which does not have one or more of the disadvantages described above. The present disclosure introduces a novel approach that leverages simulation techniques to streamline the recipe creation process, eliminating the dependency on physical wafers and reducing the reliance on manual intervention. By simulating the interaction between irradiated electrons from the electron beam tool and a specimen, as well as the collection and detection of escaped electrons under various imaging configurations, the proposed automated workflow enables the rapid generation of optimized imaging recipes with enhanced imaging performance and efficiency, as will be detailed below.

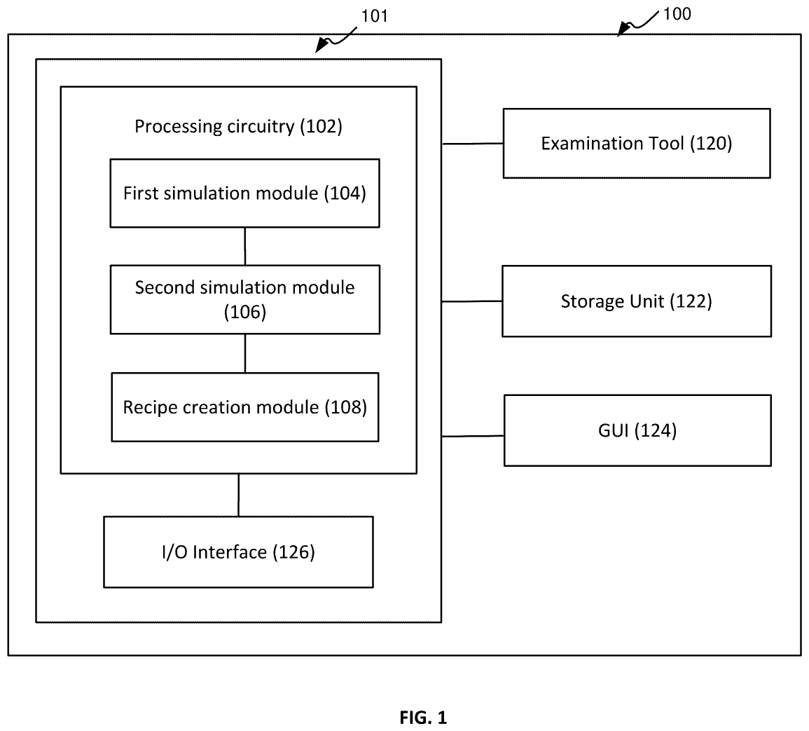

Bearing this in mind, attention is drawn to FIG. 1 illustrating a functional block diagram of an examination system in accordance with certain embodiments of the presently disclosed subject matter.

The examination system 100 illustrated in FIG. 1 can be used for examination of a semiconductor specimen (e.g., a wafer, a die, or parts thereof) as part of the specimen fabrication process. As described above, the examination referred to herein can be construed to cover any kind of operations related to defect inspection/detection, defect review, defect classification, nuisance filtration, segmentation, and/or metrology operations, such as, e.g., metrology measurements, etc., with respect to the specimen. System 100 comprises one or more examination tools 120 configured to scan a specimen and capture images thereof to be further processed for various examination applications.

The term “examination tool(s)” used herein should be expansively construed to cover any tools that can be used in examination-related processes, including, by way of non-limiting example, scanning, imaging, sampling, reviewing, measuring, classifying, and/or other processes provided with regard to the specimen or parts thereof. The examination tool(s) 120 can be implemented as machines of various types. In some embodiments, the examination tool can be implemented as an electron beam machine/tool, such as e.g., Scanning Electron Microscope (SEM) as described above, Atomic Force Microscopy (AFM), or Transmission Electron Microscope (TEM), etc.

According to certain embodiments, in some cases, the examination tool(s) 120 can include one or more inspection tools and/or one or more review tools. The inspection tools can scan the specimen to capture inspection images and detect potential defects in accordance with a defect detection algorithm. The output of the detection module is a defect map indicative of defect candidate distribution on the semiconductor specimen. The review tools can be configured to capture review images at locations of the defect candidates in the map, and review the review images for ascertaining whether a defect candidate is indeed a DOI.

In some cases, at least one of the examination tools 120 has metrology capabilities. Such an examination tool is also referred to as a metrology tool. The metrology tool can be configured to generate image data in response to scanning the specimen, and perform metrology operations based on the image data.

In some cases, the same examination tool can operate in different examination modes. The same tool can provide low-resolution image data and/or high-resolution image data. The resulting image data can be transmitted-directly or via one or more intermediate systems—to system 101. The present disclosure is not limited to any specific type of examination tools and/or the representation/resolution of image data resulting from the examination tools.

According to certain embodiments of the presently disclosed subject matter, the examination system 100 comprises a computer-based system 101 operatively connected to the examination tool 120 and capable of automatic recipe creation/optimization, as will be detailed below. System 101 is also referred to as a recipe creation or optimization system. By way of example, system 101 can be referred to as recipe optimization system in cases where there exists an initial recipe which is optimized via the proposed solution. Alternatively, it can be referred to as a recipe creation system in cases where there was no recipe and the proposed solution is used to create an imaging recipe from scratch.

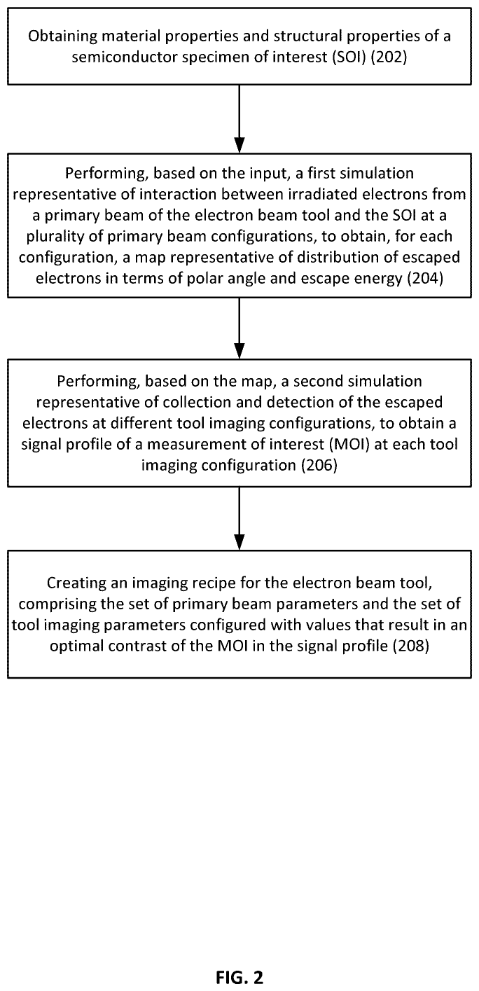

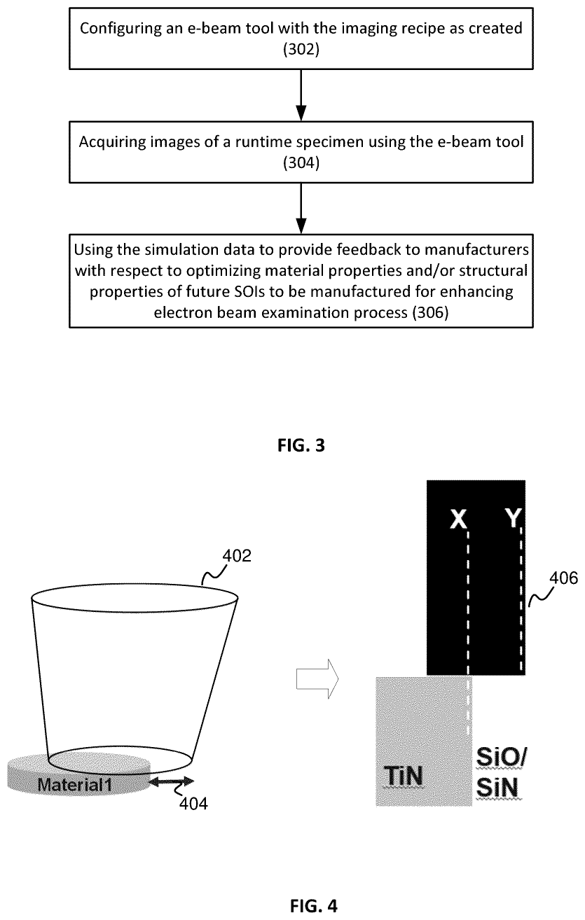

System 101 includes a processing circuitry 102 operatively connected to a hardware-based I/O interface 126 and configured to provide processing necessary for operating the system, as further detailed with reference to FIGS. 2-3. The processing circuitry 102 can comprise one or more processors (not shown separately) and one or more memories (not shown separately). The one or more processors of the processing circuitry 102 can be configured to, either separately or in any appropriate combination, execute several functional modules in accordance with computer-readable instructions implemented on a non-transitory computer-readable memory comprised in the processing circuitry. Such functional modules are referred to hereinafter as comprised in the processing circuitry.

According to certain embodiments, one or more functional modules comprised in the processing circuitry 102 of system 101 can include a first simulation module 104, a second simulation module 106 and a recipe creation module 108 operatively connected to each other.

Specifically, the processing circuitry 102 can be configured to obtain, via an I/O interface 126, material properties and structural properties of a semiconductor specimen of interest (SOI) as input. The first simulation module 104 can be configured to perform, based on the input, a first simulation representative of interaction between irradiated electrons of a primary beam of the electron beam tool and the SOI at a plurality of primary beam configurations characterized by different values of a set of primary beam parameters, to obtain, for each primary beam configuration, a map representative of distribution of escaped electrons in terms of polar angle and escape energy.

The second simulation module 106 can be configured to perform, based on the map, a second simulation representative of collection and detection of the escaped electrons at a plurality of tool imaging configurations characterized by different values of a set of tool imaging parameters, to obtain a signal profile of a measurement of interest (MOI) on the SOI at each tool imaging configuration.

The recipe creation module 108 can be configured to create an imaging recipe for the electron beam tool, comprising the set of primary beam parameters and the set of tool imaging parameters configured with values that result in an optimal contrast of the MOI in the signal profile.

It is to be noted that while certain embodiments of the present disclosure refer to the processing circuitry 102 being configured to perform the above recited operations, the functionalities/operations of the aforementioned functional modules can be performed by the one or more processors in processing circuitry 102 in various ways. By way of example, the operations of each functional module can be performed by a specific processor, or by a combination of processors. The operations of the various functional modules, such as the first simulation, the second simulation, and recipe creation, etc., can thus be performed by respective processors (or processor combinations) in the processing circuitry 102, while, optionally, these operations may be performed by the same processor. The present disclosure should not be limited to being construed as one single processor always performing all the operations.

In some cases, additionally to system 101, the examination system 100 can comprise one or more examination modules, such as, e.g., defect detection module, nuisance filtration module, Automatic Defect Review Module (ADR), Automatic Defect Classification Module (ADC), metrology operation module, and/or other examination modules which are usable for examination of a semiconductor specimen. The one or more examination modules can be implemented as stand-alone computers, or their functionalities (or at least part thereof) can be integrated with the examination tool 120. In some cases, the output of system 101, e.g., the imaging recipe, the parameter values thereof, and/or the simulation data, can be provided to the one or more examination modules for further processing.

According to certain embodiments, system 100 can comprise a storage unit 122. The storage unit 122 can be configured to store any data necessary for operating system 101, e.g., data related to input and output of system 101, as well as intermediate processing results generated by system 101. By way of example, the storage unit 122 can be configured to store the input data, e.g., the material properties and structural properties of a SOI, as described above. In some cases, the input data can be partially obtained, e.g., from a design server. Accordingly, the different types of input data as required can be retrieved from the storage unit 122 and provided to the processing circuitry 102 for further processing. The output of the system 101, such as, e.g., the imaging recipe, the parameter values thereof, and/or the simulation data, can be sent to storage unit 122 to be stored.

In some embodiments, system 100 can optionally comprise a computer-based Graphical User Interface (GUI) 124 which is configured to enable user-specified inputs related to system 101. For instance, the user can be presented with a visual representation of the SOI (for example, by a display forming part of GUI 124), such as, e.g., via the design data of the SOI. The user may be provided, through the GUI, with options of defining certain operation parameters, such as, e.g., the specific parameters involved in the first and simulations, and the values thereof, etc. The user may also view the operation results or intermediate processing results, such as, e.g., the simulation outputs (e.g., the map, the signal profile, etc.), and the various tool configurations, etc., on the GUI.

In some cases, system 101 can be further configured to send, via I/O interface 126, the operation results to the examination tool 120 for further processing. In some cases, system 101 can be further configured to send the results to the storage unit 122, and/or external systems (e.g., Yield Management System (YMS) of a fabrication plant (fab)). A yield management system (YMS) in the context of semiconductor manufacturing is a data management, analysis, and tool system that collects data from the fab, especially during manufacturing ramp ups, and helps engineers find ways to improve yield. YMS helps semiconductor manufacturers and fabs manage high volumes of production analysis with fewer engineers. These systems analyze the yield data and generate reports. YMS can be used by Integrated Device Manufacturers (IMD), fabs, fabless semiconductor companies, and Outsourced Semiconductor Assembly and Test (OSAT).

Those versed in the art will readily appreciate that the teachings of the presently disclosed subject matter are not bound by the system illustrated in FIG. 1. Each system component and module in FIG. 1 can be made up of any combination of software, hardware, and/or firmware, as relevant, executed on a suitable device or devices, which perform the functions as defined and explained herein. Equivalent and/or modified functionality, as described with respect to each system component and module, can be consolidated or divided in another manner. Thus, in some embodiments of the presently disclosed subject matter, the system may include fewer, more, modified and/or different components, modules, and functions than those shown in FIG. 1.

Each component in FIG. 1 may represent a plurality of the particular components, which are adapted to independently and/or cooperatively operate to process various data and electrical inputs, and for enabling operations related to a computerized examination system. In some cases, multiple instances of a component may be utilized for reasons of performance, redundancy, and/or availability. Similarly, in some cases, multiple instances of a component may be utilized for reasons of functionality or application. For example, different portions of the particular functionality may be placed in different instances of the component.

It should be noted that the examination system illustrated in FIG. 1 can be implemented in a distributed computing environment, in which one or more of the aforementioned components and functional modules shown in FIG. 1 can be distributed over several local and/or remote devices. By way of example, as described above, in some cases, system 101 can be configured as a recipe creation/setup system for creating the imaging recipe (or a recipe optimization system for optimizing an initial recipe). Upon creation/optimization, the recipe can be used in runtime to configure an examination tool usable for examining a runtime specimen. The examination tool 120 and the system 101 can be located at the same entity (in some cases hosted by the same device) or distributed over different entities, depending on specific system configurations and implementation needs.

In some examples, certain components utilize a cloud implementation, e.g., are implemented in a private or public cloud. Communication between the various components of the examination system, in cases where they are not located entirely in one location or in one physical entity, can be realized by any signaling system or communication components, modules, protocols, software languages, and drive signals, and can be wired and/or wireless, as appropriate.

It should be further noted that in some embodiments at least some of examination tool 120, storage unit 122 and/or GUI 124 can be external to the examination system 100 and operate in data communication with systems 100 and 101 via I/O interface 126. System 101 can be implemented as stand-alone computer(s) to be used in conjunction with the examination tools, and/or with the additional examination modules as described above. Alternatively, the respective functions of the system 101 can, at least partly, be integrated with one or more of examination tool 120, thereby facilitating and enhancing the functionalities of the examination tools in examination-related processes.

While not necessarily so, the process of operations of systems 101 and 100 can correspond to some or all of the stages of the methods described with respect to FIGS. 2-3. Likewise, the methods described with respect to FIGS. 2-3 and their possible implementations can be implemented by systems 101 and 100. It is therefore noted that embodiments discussed in relation to the methods described with respect to FIGS. 2-3 can also be implemented, mutatis mutandis as various embodiments of the systems 101 and 100, and vice versa.

Referring to FIG. 2, there is illustrated a generalized flowchart of automatic recipe creation/optimization in accordance with certain embodiments of the presently disclosed subject matter.

As described above, a semiconductor specimen is typically made of multiple layers. The examination process of a specimen can be performed a multiplicity of times during the fabrication process of the specimen, for example following the processing steps of specific layers. In some cases, a sampled set of processing steps can be selected for in-line examination, based on their known impacts on device characteristics or yield. Images of the specimen or parts thereof can be acquired at the sampled set of processing steps to be examined.

For the purpose of illustration only, certain embodiments of the following description are described with respect to imaging for a given processing step/layer of the sampled set of processing steps. Those skilled in the art will readily appreciate that the teachings of the presently disclosed subject matter can be performed for any layer and/or processing steps of the specimen. The present disclosure should not be limited to the number of layers comprised in the specimen and/or the specific layer(s) to be imaged.

As input, the physical properties of a semiconductor specimen of interest (SOI), such as structural properties and material properties, can be obtained (202) (e.g., from the storage unit 122). In some cases, these properties can be collectively referred to as the “stack information” of the specimen. Stack information generally refers to a comprehensive set of properties characterizing the layered architecture of a specimen. This information encompasses parameters defining the hierarchical arrangement and physical attributes of the specimen's constituent layers. The stack information serves as a foundational dataset for simulation modeling and analysis, enabling accurate representation and predictive assessment of the specimen's behavior under various conditions, including electron irradiation in semiconductor imaging applications.

Specifically, the structural properties of a specimen in general delineate the spatial arrangement and dimensional characteristics of the specimen's constituent layers and structural features/elements on the layers. In some cases, at least part of the structural properties can be obtained from design data (e.g., CAD) of the specimen. By way of example, the structural properties can comprise one or more of the following: layer layout (e.g., the arrangement and sequence of semiconductor layers within the SOI stack), thickness (e.g., the vertical dimension of each layer, which exerts influence on electron penetration depth and signal generation), and geometric dimensions of structural features on each layer (e.g., the lateral dimensions and shapes of structural elements within each layer, such as line widths, spacing, and geometrical features).

The material properties of a specimen encompass a multitude of factors that may influence its behavior under electron irradiation. By way of example, the material properties can comprise one or more of the following: composition (e.g., the elemental composition which may impact the scattering and absorption of electrons), density (e.g., the mass per unit volume of the materials within the SOI, influencing the propagation and attenuation of the electron beam as it traverses through the specimen), and stoichiometric formula of materials constituting the specimen. The stoichiometric formula can refer to the chemical formula representing the stoichiometry of compounds within the semiconductor layers, which may be needed for accurately modeling the distribution of atoms and the formation of crystal structures.

It is to be noted that the above properties are listed for exemplary purposes only, and should not be regarded as limiting the present disclosure in any way. Any other similar properties can be used in addition to or in lieu of the above. By way of example, in some cases, the material properties may include additional properties, such as, e.g., surface roughness, lattice arrangement, etc. In some cases, the material properties may include additional properties, such as optical, mechanical, chemical and/or magnetic properties of the materials of the SOI, which, in combination, can provide a more comprehensive characterization of the semiconductor specimen, facilitating a more accurate simulation of electron-semiconductor interactions, as well as collection and detection of the electrons.

FIG. 4 illustrates an example of a specimen of interest (SOI) and a measurement of interest (MOI) on the SOI in accordance with certain embodiments of the presently disclosed subject matter.

In the example, the specimen of interest (SOI) comprises a Vertical NAND (V-NAND) (also referred to as 3D-NAND) structure. The V-NAND structure employs a three-dimensional stacking of memory layers to increase data storage density in semiconductor devices. In particular, a two-tier process, also known as tier stacking, splits the V-NAND stack into two tiers to accommodate the increasing aspect ratio of channel holes. Each tier contains alternating layers of dielectric materials and conductive materials. Within each tier, channel holes are etched to create vertical conduits for electrical communication between layers. The two-tier process typically introduces challenges in achieving precise alignment between the channel holes of different tiers.

The measurement of interest on the SOI refers to an overlay measurement focusing on quantifying the relative placement/alignment of channel hole stacks between adjacent tiers. For instance, the overlay measurement can be represented by a shift/offset between the bottom of an upper tier/deck and the top of the lower tier/deck.

FIG. 4 shows a simplified schematic illustration, where an upper channel hole 402 of an upper tier and a material 1 (such as, e.g., Titanium Nitride (TiN)) of a lower tier. The overlay can be measured at the interface of the two tiers, as the shift 404 between the bottom of the channel hole 402 and the top of material 1. FIG. 4 also illustrates a cross-section view 406 demonstrating the shift as a distance between two locations X and Y representative of the right edges of material 1 (TiN) and the channel hole 402 within another material (e.g., Silicon Monoxide (SiO)/Silicon Nitride (SiN)).

In some cases, it is desired that the measurement can achieve the highest possible contrast between the upper tier and the lower tier (contrast refers to the difference in signal intensity or electron density between the two tiers), which directly affects the accuracy and precision of overlay measurements. By optimizing the contrast between the tiers, the accuracy and reliability of overlay measurements can be improved, enabling more precise alignment and alignment correction processes in semiconductor manufacturing.

The proposed simulation-based recipe generation can be used to optimize overlay contrast obtained when imaging V-NAND specimens. By simulating the interaction between irradiated electrons and the V-NAND structure and the detection of the escaped electrons at various tool imaging configurations, the solution enables the identification of optimal imaging parameters that maximize the contrast between the upper and lower tiers, as will be detailed below.

Once the input is obtained, a first simulation can be performed (204) (e.g., by the first simulation module 104) based on the input, representative of interaction between irradiated electrons of a primary beam of the electron beam tool (also referred to as e-beam tool) and the SOI at a plurality of primary beam configurations. The plurality of primary beam configurations are characterized by different values of a set of primary beam parameters. Upon the first simulation, for each primary beam configuration, a map can be obtained (as an output of the first simulation), representative of distribution of escaped electrons in terms of polar angle and escape energy.

An e-beam tool is typically configured with multiple tool parameters characterizing the tool, including, such as, e.g., a set of primary beam parameters and a set of tool imaging parameters. By way of example, the set of primary beam parameters characterize the primary beam emitted from the electron source of the e-beam tool, and can comprise at least some of the following parameters: landing energy, beam resolution, current amplitude, current density, electron source characteristics, lens settings, aperture size, and numerical aperture (NA), which collectively define the characteristics of the primary beam, such as the spatial extent and focus of the beam.

The first simulation aims to model the interaction between irradiated electrons of the primary beam and the SOI across a range of primary beam configurations. This simulation is usable for understanding how variations in primary beam parameters influence electron-SOI interactions and the resulting behavior of escaped electrons within the system.

According to certain embodiments, the first simulation can start with an initial setup of a plurality of primary beam configurations. The plurality of primary beam configurations are characterized by a plurality of combinations of different/varying values of the set of primary beam parameters, as described above. By way of example, the value of each parameter from the set of primary beam parameters can be varied a number of times, giving rise to a plurality of primary beam configurations corresponding to a plurality of combinations of varying values of the set of primary beam parameters. For instance, the value of a given parameter, such as landing energy, can be varied within a predefined range in accordance with an interval or step size. The varying values of different parameters can be combined differently, constituting the plurality of primary beam configurations.

At each primary beam configuration, the first simulation simulates the primary beam being directed towards the SOI, where interactions occur based on the material and structural properties previously defined. By way of example, electron-solid interactions, including secondary electron emission, electron back-scattering, absorption, etc., can be simulated to elucidate the distribution and behavior of primary and escaped electrons within the specimen. The simulation can also track the trajectories of irradiated electrons as they traverse through the SOI, considering the effects of parameters, such as varying landing energy, beam resolution, and current density, on electron transport and interaction mechanisms within the material.

Upon interaction with the SOI, a subset of electrons, such as secondary electrons (SEs), and/or backscattered electrons (BSEs), may escape from the specimen surface, carrying information on its composition, dimensions, defectivity, and surface characteristics. The traces of these escaped electrons are tracked using a tracing algorithm, accounting for their energy, direction, and scattering behavior as they propagate through the tool. Specifically, in some embodiments, the tracing algorithm can use two models, a model characterizing the e-beam tool's column (which houses the electron source and lenses) (also referred to as a column model), and a model characterizing the e-beam tool's chamber (e.g., the vacuum chamber housing the specimen) (also referred to as a chamber model).

By way of example, the column model can be constructed, incorporating geometrical dimensions and material compositions of each component in the column to simulate electron optics and beam propagation. This model accounts for electron scattering, focusing, and deflection mechanisms within the column, ensuring accurate representation of electron trajectories as they interact with the SOI. A chamber model can be developed to characterize the electrostatic and electromagnetic fields within the machine chamber surrounding the electron beam tool. This model considers the spatial distribution of charge, potential, and magnetic fields generated by the electron beam and other system components, such as vacuum pumps, shielding, and stage mechanisms.

For each primary beam configuration, the simulation can generate output data, e.g., in the form of a map, representing the spatial distribution of escaped electrons in terms of polar angle and escape energy.

The term “polar angle” refers to the angle measured from a reference axis (e.g., the optical axis, which is the surface normal) to the direction in which an electron escapes from the specimen. In the context of electron microscopy, this angle provides information on the directionality of electron emission from the specimen surface. A polar angle of 0 degrees would correspond to electrons escaping perpendicular to the surface, while larger angles represent deviations from this perpendicular direction. The term “escape energy” represents the kinetic energy of the escaped electrons as they leave the specimen surface.

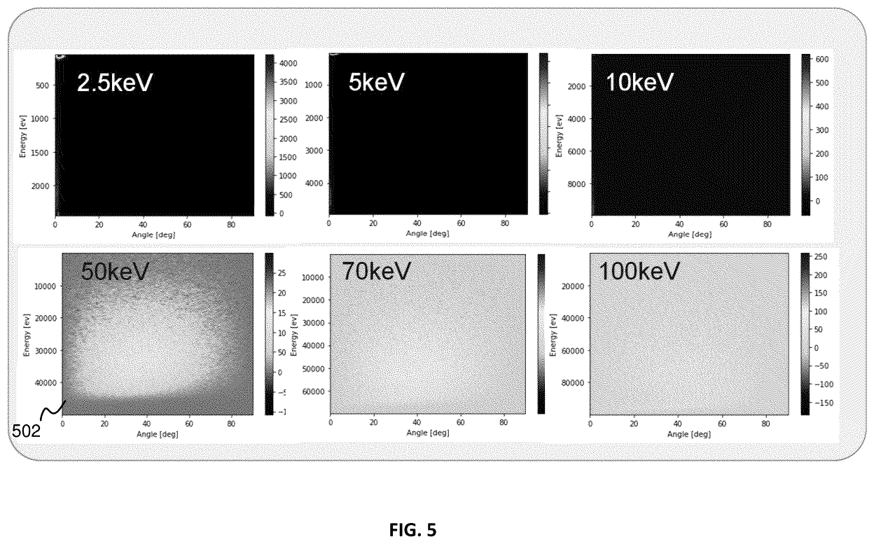

FIG. 5 illustrates an example of output data of the first simulation in accordance with certain embodiments of the presently disclosed subject matter.

To continue with the example of FIG. 4, the first simulation is performed to represent the interaction between irradiated electrons of a primary beam of the electron beam tool and the SOI (e.g., V-NAND). For purpose of easy illustration, in the present example, the plurality of primary beam configurations are characterized by different values of landing energies, e.g., at 2.5 keV, 5 keV, 10 keV, 50 keV, 70 keV, and 100 keV respectively. The output data, presented in the form of a map (also referred to as an output map), is generated corresponding to each given landing energy, representing the spatial distribution of escaped electrons at the given landing energy. As illustrated, six maps are obtained, corresponding to the six landing energies listed above.

A map typically includes a two-dimensional representation, where each pixel or grid point corresponds to a specific combination of polar angle (in the X axis) and escape energy (in the Y axis). The intensity or color of each pixel indicates the number or intensity of escaped electrons observed at that particular polar angle and escape energy bin.

These output maps provide valuable information on the spatial distribution and energy spectrum of escaped electrons, informing subsequent steps in the imaging recipe optimization process. By analyzing how different primary beam configurations influence the distribution of escaped electrons, it is possible to identify optimal beam settings for parameters such as landing energy, beam resolution, and numerical aperture to enhance imaging performance and sensitivity. By way of example, by correlating escape energy/polar angle with the specific beam configurations, it is possible to tailor the selection of beam parameters to maximize signal contrast, resolution, and sensitivity for detecting/measuring features of interest within the specimen.

For instance, in the example of FIG. 5, by analyzing the six output maps, it can be identified that the map 502, which is generated at a landing energy of 50 keV, provides the best signal contrast and sensitivity, in particular within the range of polar angle of 20-60 degrees. Therefore, it can be derived that the optimal landing energy for imaging should be around 50 keV, while a detector having a polar angle within the range of 20-60 degrees should be utilized for collecting the escaped electrons. In addition, from the Y axis, it can be identified that the best signal contrast and sensitivity is provided at an energy level of escaped electrons between 20 keV and 40 keV. The output map from the first simulation thus serves as a foundation for guiding parameter optimization and recipe generation in subsequent steps.

Continuing with the description of FIG. 2, upon the first simulation being performed and the output map being obtained, a second simulation can be performed (206) (e.g., by the second simulation module 106) based on the map, where the second simulation is representative of collection and detection of the escaped electrons at a plurality of tool imaging configurations. The plurality of tool imaging configurations are characterized by different values of a set of tool imaging parameters. Upon the second simulation, a signal profile of a measurement of interest (MOI) on the SOI can be obtained (as the output of the second simulation) at each tool imaging configuration.

The set of tool imaging parameters, as part of the tool parameters. characterize the collection and detection of the escaped electrons so as to form an imaging signal. By way of example, the set of tool imaging parameters can comprise at least some of the following parameters: detector angle, detector gain, defector offset, electrostatic field, voltage, mechanical configuration, dwell time, scanning speed, pixel size, and energy filter of the electron beam tool.

Similarly, the second simulation can start with an initial setup of a plurality of tool imaging configurations. The plurality of tool imaging configurations are characterized by a plurality of combinations of different/varying values of the set of tool imaging parameters. By way of example, the value of each parameter from the set of tool imaging parameters can be varied a number of times, giving rise to a plurality of tool imaging configurations corresponding to a plurality of combinations of varying values of the set of tool imaging parameters. Each configuration represents a unique combination of these parameters, defining the conditions under which escaped electrons are collected and detected.

In some embodiments, at each tool imaging configuration, the second simulation models the collection of escaped electrons by different detectors positioned at specific angles and orientations relative to the SOI. The output map from the first simulation can be used as an input to the second simulation, to determine the expected distribution of escaped electrons entering different detectors at each tool imaging configuration. This involves modeling the trajectories of escaped electrons as they travel from the specimen surface to the detectors. The efficiency of electron collection can be influenced by parameters such as, e.g., detector angle, deflector offset, and electrostatic field, which determine the trajectories of escaped electrons towards the detectors.

The second simulation then models the detection of the collected electrons by the detectors to generate a signal profile of a measurement of interest (MOI). In one example, the signal detected by a given detector can be simulated, based on a correlation between the detector gain and the hitting energy (e.g., the energy level at which the electrons hit/enter the detector, also referred to as energy of incoming electrons of the detector), and optionally also hitting current (e.g., the current level at which the electrons hit/enter the detector, also referred to as current of incoming electrons of the detector).

FIG. 8 illustrates an example of such a correlation relationship between the detector gain, the hitting energy and the hitting current in accordance with certain embodiments of the presently disclosed subject matter. In the graph, the X axis represents the hitting energy, while the Y axis represents the detector gain. The four dotted curves in the graph correspond to four different hitting currents. This correlation may reflect the empirical dependence of detector gain on the energy and the current of incoming electrons of the detector. Such correlation can allow to select the best/optimal imaging condition that meets the performance requirements for different applications (such as, e.g., to detect feature of interest such as defects, to be sensitive enough to spot the abnormality in dimensions, such as in CD measurements, etc.). By incorporating such correlation into the simulation, the signal intensity detected by the detector can be more accurately predicted for each tool imaging configuration.

The signal profile of the measurement of interest (MOI) is generated for each tool imaging configuration. The signal profile represents the intensity or count rate of detected electrons as a function of various tool imaging parameters, such as detector gain, voltage, and detector offset, etc. By analyzing the signal profiles obtained for different tool imaging configurations, it is possible to assess the imaging performance and measurement sensitivity of the electron beam tool under varying conditions.

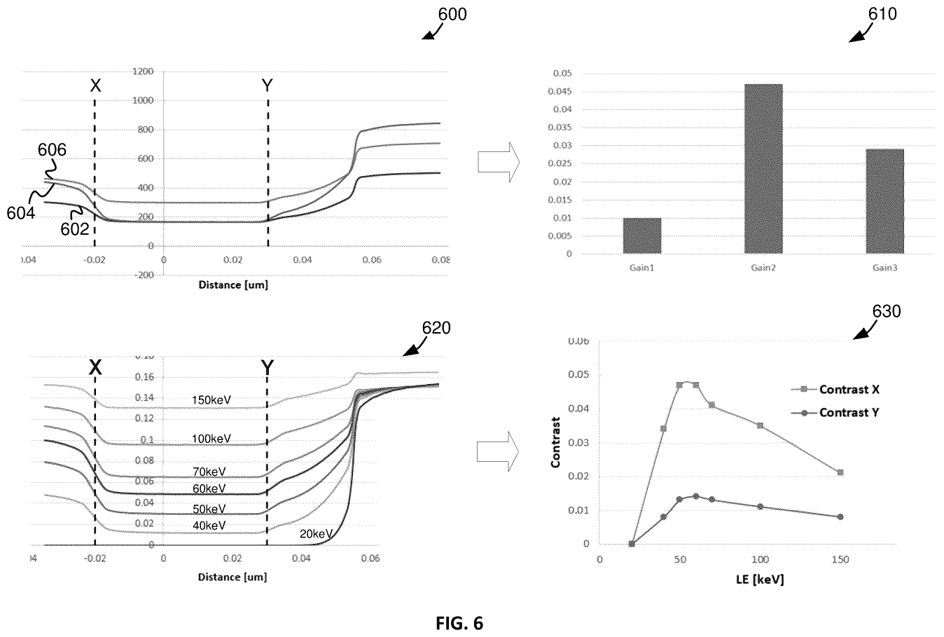

FIG. 6 illustrates an example of signal profiles resulting from the second simulation in accordance with certain embodiments of the presently disclosed subject matter.

Continuing with the example of FIG. 5, graph 602 illustrates signal profiles obtained at a landing energy of 50 keV, which can provide the optimal signal intensity and sensitivity according to the analysis of the output maps from FIG. 5. The signal profiles represent the signal intensity across the surface of the V-NAND specimen. The X-axis of the graph 602 represents the distance along the scanning line across the surface of the V-NAND specimen, while the Y-axis represents the signal intensity (or the number of detected electrons). The graph 602 includes three signal profile curves, each corresponding to a different detector gain setting. Specifically, curve 602 corresponds to detector gain 1, curve 604 corresponds to detector gain 2, and curve 606 corresponds to detector gain 3.

Detector gain refers to the amplification factor applied to the signal detected by a detector in an imaging system. In electron beam imaging, detector gain determines the extent to which the detected signal is amplified before being processed and displayed as an image or signal profile. A higher detector gain amplifies the detected signal more, enhancing the sensitivity of the detector to low-intensity signals. This can improve the visibility of features in the specimen being imaged, particularly those with low contrast or low electron density. However, increasing the detector gain also amplifies noise and background signals, which can degrade image quality and reduce the ability to distinguish between signal and noise. Therefore, the choice of detector gain involves a trade-off between signal amplification and noise amplification.

The curves 602, 604, and 606 depict the variation in signal intensity along the scanning line for different detector gain configurations. Different detector gain settings are tested to determine which configuration provides the best contrast for accurately detecting the overlay between the upper channel hole and the lower material layer.

The contrast at the two X and Y locations can be calculated from the signal profiles in graph 600. Graph 610 illustrates the calculated contrasts (e.g., averaged contrast) at the three detector gains. By way of example, it can be seen from graph 610 that detector gain 2 provides the best contrast at X and Y locations which is optimal for measuring the overlay between the upper channel hole and material 1. The optimization of detector gain can help enhance the accuracy and reliability of overlay measurement in semiconductor manufacturing processes.

It is to be noted that although the second simulation for deriving graph 600 is performed at a given landing energy of 50 keV, this is for exemplary and illustrative purposes only, and should not be regarded as limiting the present disclosure. Although, when performing the second simulation, it can be more efficient to take into consideration the insights from the first simulation (such as, e.g., the landing energy of 50 keV provides the best signal intensity an sensitivity in the first simulation), in some cases, the second simulation can be performed respectively at a range of different landing energies, such as those used in the first simulation as illustrated in FIG. 5. In some cases, the second simulation can be performed based on more tool imaging parameters, in addition to detector gain as exemplified in FIG. 6. In such cases, the signal profile can be represented in a multi-dimensional parameter space.

In some embodiments, the first simulation, focused on modeling the interaction between irradiated electrons and the specimen, and the second simulation, aimed at simulating the collection and detection of escaped electrons at various tool imaging configurations, can be integrated into a consolidated simulation framework. This consolidated simulation enables the comprehensive optimization of tool configurations characterized by both primary beam parameters and tool imaging parameters.

The consolidated simulation framework models the complete electron-solid interaction process, including the irradiation of electrons from the primary beam tool, their interaction with the specimen, and the subsequent collection and detection of escaped electrons at various tool imaging configurations. This comprehensive modeling approach captures the complex interplay between primary beam parameters and tool imaging parameters, providing insights into their combined influence on signal intensity, contrast, and measurement sensitivity.

Through possible iterations, the consolidated simulation explores a wide range of tool configurations characterized by different combinations of primary beam parameters and tool imaging parameters. By systematically varying these parameters, the simulation seeks to identify optimal configurations that maximize signal contrast, enhance measurement sensitivity, and improve imaging performance for specific measurements and/or specimen types.

The consolidated simulation generates output data such as signal profiles or images representing the measured characteristics of the specimen at each tool configuration (characterized by primary beam parameters and/or tool imaging parameters). By way of example, graph 620 illustrates signal profiles directly obtained at a range of various landing energies (which is a primary beam parameter). The X-axis of the graph 620 represents the distance along the scanning line across the surface of the V-NAND specimen, while the Y-axis represents the signal-to-noise ratio (SNR) of the detected signal. Specifically, the graph 620 includes seven signal profile curves, each corresponding to a different landing energy setting (from top to bottom). Specifically, the curves from top to bottom correspond to the landing energies of 150, 100, 70, 60, 50, 4, and 20 keV.

Similarly, graph 630 illustrates the calculated contrasts at X and Y locations for the range of landing energies. By way of example, it can be seen from graph 630 that the landing energy of 50 keV provides the best contrast at X and Y locations which is optimal for measuring the overlay between the upper channel hole and material 1.

It is to be understood that the signal profiles simulated at different landing energies, as shown in graph 620, are for illustrative purposes only. While this example focuses on variations in a single primary beam parameter, namely landing energy, it is understood that the optimization of tool configurations often involves multiple parameters, including both primary beam parameters and tool imaging parameters. The simulation of tool configurations characterized by multiple parameters, such as combinations of primary beam parameters and tool imaging parameters, results in a multi-dimensional representation of the signal profile in parameter space. Due to the complexity of visualizing multi-dimensional data in drawings, this example simplifies the illustration by focusing on variations in a single primary beam parameter. It is anticipated that persons skilled in the art will appreciate that the example provided can be understood as representative of simulations based on multiple parameters, despite only showing variations in one parameter.

The consolidated simulation approach offers several advantages, including a more holistic understanding of the impact of different tool parameters, enhanced efficiency in parameter optimization, and possibly improved accuracy in predicting imaging outcomes.

Continuing with the description of FIG. 2, upon completion of the second simulation, an imaging recipe can be created (208) (e.g., by the recipe creation module 108) for the electron beam tool. The imaging recipe comprises the set of primary beam parameters and the set of tool imaging parameters configured with values that result in an optimal contrast of the MOI in the signal profile.

Based on the signal profiles obtained from the second simulation, parameter values are identified that maximize the contrast of the MOI. This may involve analyzing the impact of different primary beam parameters, such as landing energy, beam resolution, and current amplitude, as well as tool imaging parameters, such as detector angle, gain, and electrostatic field, on signal intensity and contrast.

By way of example, when analyzing the signal profiles in graph 600 of FIG. 6, it can be derived that the optimal contrast for the MOI in this example can be obtained at a detector gain 2, and at a landing energy of 50 keV. In addition, when analyzing the output from the first simulation, such as the graph 502 in FIG. 5, it can be identified that a range of polar angle of 20-60 degrees and an energy level of escaped electrons between 20 keV and 40 keV can provide the best signal contrast and sensitivity. Therefore, it can be derived that a detector positioned at a polar angle within the selected range of 20-60 degrees (also referred to as a side detector), with an energy filter for capturing an energy level of escaped electrons between 20 keV and 40 keV (or energy filter for filtering out escaped electrons with unwanted energy levels), should be utilized for enabling the optimal imaging of the specimen.

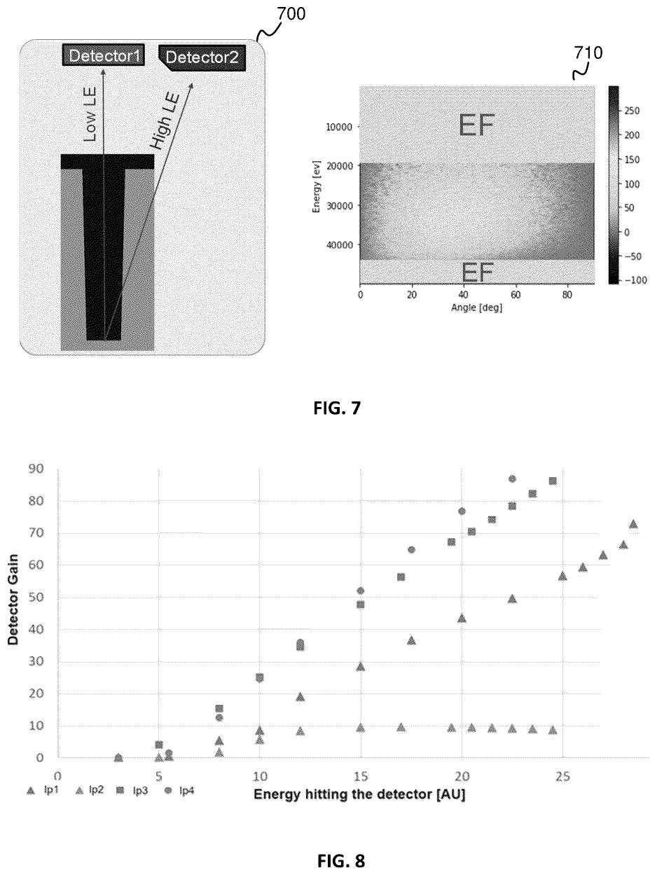

FIG. 7 provides a schematic illustration of detectors and energy filters utilized for optimal imaging of the specimen in accordance with certain embodiments of the presently disclosed subject matter.

Illustration 700 shows two detectors collecting escaped electrons from a channel hole of a specimen. Detector 1 is a top detector positioned at a polar angle of 0 degrees relative to the optical axis. This detector collects electrons emitted from the specimen in the direction perpendicular to the specimen surface. It is often used for detecting secondary electrons (SE) and provides valuable information on surface topography.

Detector 2 is a side detector positioned at a polar angle of around 30 degrees. This detector collects electrons emitted from the specimen at the given polar angle. It is particularly effective for detecting backscattered electrons (BSE) and offers insights into material composition and density variations within the specimen. In the example of FIG. 5 described above, detector 2 is located within the range of a polar angle of 20-60 degrees that provides optimal signal intensity/sensitivity, thus should be selected for collection and detection of imaging signals.

Graph 710 is a revised version of graph 502, where two energy filters (marked as EF) are used to filter out the unwanted energy levels of escaped electrons, ensuring that only electrons within the desired energy range are detected and analyzed. The two energy filters can be implemented, e.g., using band pass filters. Specifically, a lower energy filter filters out electrons with energy levels below the desired range (e.g., 10-20 keV), preventing them from reaching the detector, and a higher energy filter filters out electrons with energy levels above the desired range (e.g., above 40 keV), eliminating interference from high-energy electrons in the signal detection process.

Although not illustrated in FIG. 7, the detector gain of the e-beam tool can also be configured to be at detector gain 2, while the landing energy can be configured to be 50 keV, which provides the optimal contrast for the MOI. The selection of a side detector, two energy filters, the detector gain, and the landing energy, can be included in the imaging recipe usable for configuring an e-beam tool, which, when being used to scan a SOI, can result in an optimal contrast for the MOI (e.g., the overlay measurement).

The imaging recipe resulting from the proposed flow in FIG. 2 is referred to as a wafer-less recipe which is created without the need for acquiring and scanning an actual SOI, enabling improved time-to-recipe.

Turning now to FIG. 3, there is illustrated a generalized flowchart of using the created imaging recipe in accordance with certain embodiments of the presently disclosed subject matter.

The imaging recipe and simulation data resulting from the proposed solution offer diverse applications and functionalities across various stages of semiconductor manufacturing and examination processes.

In some embodiments, an e-beam tool can be configured (302) using the imaging recipe as created. The configured tool can be used in runtime to acquire (304) images of a runtime specimen to be examined. By applying the optimized parameter values specified in the imaging recipe, it is likely to ensure consistent and reliable imaging performance, facilitating precise analysis and characterization of semiconductor materials and devices.

Optionally, simulation data of the first simulation and/or the second simulation (e.g., the simulation results from the first/second simulation) can be used (306) to provide feedback to manufacturers with respect to optimizing material properties and/or structural properties of future SOIs to be manufactured. The material properties and/or structural properties are to be optimized for improving/facilitating the examination process by an electron beam tool. By analyzing the relationships among the physical properties, imaging parameters and signal characteristics, manufacturers can identify opportunities to optimize material and structural designs/properties when designing/manufacturing future SOIs, which can improve electron beam tool compatibility and imaging performance, thus enhancing the examination performance. By way of example, based on the simulation results, the customer can add a material with a high atomic number to the stack of the specimen in order to improve materials contrast.

Optionally, the simulation data of the first simulation and/or the second simulation can be usable to design a new e-beam tool with one or more tool parameters configured with one or more selected values. By way of example, insights gained from the simulations can inform the selection of tool parameters and configurations optimized for specific imaging tasks and/or analytical requirements. By designing e-beam tools with tailored features/parameters, it is possible to improve imaging efficiency and effectiveness in semiconductor analysis and manufacturing workflows. For instance, an e-beam tool can be designed with a side detector positioned at a selected polar angle, so as to receive the escaped electrons at the selected angle which was proven (e.g., by the first simulation) to be able to provide an optimal signal intensity/sensitivity and result in an optimal contrast of the MOI. The integration of simulation data into the design process enables to develop next-generation e-beam tools with improved performance and versatility.

The proposed simulation-based framework can be applied across various semiconductor structures and manufacturing processes, including but not limited to V-NAND fabrication, to optimize tool configurations and enhance imaging capabilities.

It is to be noted that examples illustrated in the present disclosure, such as, e.g., the exemplified structures, the simulation graphs, various tool parameters, the specific configurations, etc., are illustrated for exemplary purposes, and should not be regarded as limiting the present disclosure in any way. Other appropriate examples/implementations can be used in addition to, or in lieu of the above.

Among advantages of certain embodiments of the presently disclosed subject matter as described herein, is providing an automatic recipe creation/optimization system capable of creating a wafer-less recipe without the need for acquiring and scanning an actual SOI, thereby enabling improved time-to-recipe.

As compared to traditional recipe creation methods which require significant resources, such as materials, equipment, and labor, thus introducing delays in recipe development and implementation, the proposed solution leverages simulation-based approaches to generate imaging recipes directly from simulation models of electron-solid interactions and signal collection/detection. The solution bypasses the need for physical samples, enabling rapid recipe development and optimization, and significant cost reduction. By leveraging simulations, it can reduce reliance on experimental trial and error in recipe development and optimization.

In addition, the wafer-less recipe approach also enhances efficiency and flexibility in semiconductor manufacturing workflows. Without the constraints imposed by physical sample availability and processing, the simulation-based approach can quickly iterate through different tool configurations, experiment with parameter settings, and optimize imaging recipes to meet specific performance requirements.

Among further advantages of certain embodiments of the presently disclosed subject matter as described herein, is using the first and second simulations in combination, where the first simulation predicts the initial characteristics of emitted signals based on electron-solid interactions, while the second simulation predicts the final signal profiles collected by detectors under different tool configurations. The correlation and combination of the two simulations streamlines the exploration of parameter space by providing a structured framework for evaluating the impact of various parameters on imaging performance.

In particular, the second simulation, which is performed on top of the first simulation, allows for precise fine-tuning of tool imaging parameters, such as detector angle, gain, and electrostatic field, etc., to optimize signal collection and detection. This level of control enhances the sensitivity, resolution, and overall quality of imaging results, enabling more accurate analysis and characterization of semiconductor materials and devices.

It allows to generate customized signal profiles for specific MOIs on specific SOIs by simulating signal collection under different tool configurations. This capability enables tailoring of imaging recipes to match the unique characteristics of specimens/measurements, ensuring optimal contrast, sensitivity, and imaging performance for diverse applications.

In addition, by analyzing the results of the second simulation, manufacturers gain valuable insights into the design and development of next-generation electron beam tools. The simulation highlights the importance of specific tool parameters and configurations in achieving optimal imaging outcomes, guiding the design of innovative features and functionalities that enhance tool performance and competitiveness in the market.

It is to be understood that the present disclosure is not limited in its application to the details set forth in the description contained herein or illustrated in the drawings.

In the present detailed description, numerous specific details are set forth in order to provide a thorough understanding of the disclosure. However, it will be understood by those skilled in the art that the presently disclosed subject matter may be practiced without these specific details. In other instances, well-known methods, procedures, components, and circuits, have not been described in detail so as not to obscure the presently disclosed subject matter.

Unless specifically stated otherwise, as apparent from the present discussions, it is appreciated that throughout the specification discussions utilizing terms such as “obtaining”, “examining”, “performing”, “simulating”, “creating”, “configuring”, “measuring”, “providing”, “optimizing”, “enabling”, or the like, refer to the action(s) and/or process(es) of a computer that manipulate and/or transform data into other data, said data represented as physical, such as electronic, quantities and/or said data representing the physical objects.

The terms “computer” or “computer-based system” should be expansively construed to cover any kind of hardware-based electronic device with a data processing circuitry (e.g., digital signal processor (DSP), a graphics processing unit (GPU), a field programmable gate array (FPGA), including, by way of non-limiting example, the examination system, the recipe creation/optimization system, and respective parts thereof disclosed in the present application. The data processing circuitry (designated also as processing circuitry) can comprise, for example, one or more processors operatively connected to computer memory, loaded with executable instructions for executing operations, as further described below. The data processing circuitry encompasses a single processor or multiple processors, which may be located in the same geographical zone, or may, at least partially, be located in different zones, and may be able to communicate together.

The one or more processors referred to herein can represent one or more general-purpose processing devices such as a microprocessor, a central processing unit, or the like. More particularly, a given processor may be one of a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices such as an application specific integrated circuit (ASIC), a field programmable gate array (FPGA), a digital signal processor (DSP), a network processor, or the like. The one or more processors are configured to execute instructions for performing the operations and steps discussed herein.

The memories referred to herein can comprise one or more of the following: internal memory, such as, e.g., processor registers and cache, etc., main memory such as, e.g., read-only memory (ROM), flash memory, dynamic random access memory (DRAM) such as synchronous DRAM (SDRAM) or Rambus DRAM (RDRAM), etc.

The terms “non-transitory memory” and “non-transitory storage medium” used herein should be expansively construed to cover any volatile or non-volatile computer memory suitable to the presently disclosed subject matter. The terms should be taken to include a single medium or multiple media (e.g., a centralized or distributed database, and/or associated caches and servers) that store the one or more sets of instructions. The terms shall also be taken to include any medium that is capable of storing or encoding a set of instructions for execution by the computer and that cause the computer to perform any one or more of the methodologies of the present disclosure. The terms shall accordingly be taken to include, but not be limited to, a read only memory (“ROM”), random access memory (“RAM”), magnetic disk storage media, optical storage media, flash memory devices, etc.

The term “specimen” used in this specification should be expansively construed to cover any kind of physical objects or substrates including wafers, masks, reticles, and other structures, combinations and/or parts thereof used for manufacturing semiconductor integrated circuits, magnetic heads, flat panel displays, and other semiconductor-fabricated articles. A specimen is also referred to herein as a semiconductor specimen, and can be produced by manufacturing equipment executing corresponding manufacturing processes.

The term “examination” used in this specification should be expansively construed to cover any kind of operations related to defect detection, defect review, and/or defect classification of various types, segmentation, and/or metrology operations during and/or after the specimen fabrication process. Examination is provided by using non-destructive examination tools during or after manufacture of the specimen to be examined. By way of non-limiting example, the examination process can include runtime scanning (in a single or in multiple scans), imaging, sampling, detecting, reviewing, measuring, classifying, and/or other operations provided with regard to the specimen or parts thereof, using the same or different inspection tools. Likewise, examination can be provided prior to manufacture of the specimen to be examined, and can include, for example, generating an examination recipe(s) and/or other setup operations. It is noted that, unless specifically stated otherwise, the term “examination”, or its derivatives used in this specification, is not limited with respect to resolution or size of an inspection area. A variety of non-destructive examination tools includes, by way of non-limiting example, scanning electron microscopes (SEM), atomic force microscopes (AFM), optical inspection tools, etc.

The term “metrology operation” used in this specification should be expansively construed to cover any metrology operation procedure used to extract metrology information relating to one or more structural elements on a semiconductor specimen. In some embodiments, the metrology operations can include measurement operations, such as, e.g., critical dimension (CD) measurements performed with respect to certain structural elements on the specimen, including but not limiting to the following: dimensions (e.g., line widths, line spacing, contact diameters, size of the element, edge roughness, gray level statistics, etc.), shapes of elements, distances within or between elements, related angles, overlay information associated with elements corresponding to different design levels, etc. Measurement results, such as measured images, are analyzed, for example, by employing image-processing techniques. Note that, unless specifically stated otherwise, the term “metrology”, or derivatives thereof used in this specification, is not limited with respect to measurement technology, measurement resolution, or size of inspection area.

The term “defect” used in this specification should be expansively construed to cover any kind of abnormality or undesirable feature/functionality formed on a specimen. In some cases, a defect may be a defect of interest (DOI) which is a real defect that has certain effects on the functionality of the fabricated device, thus is in the customer's interest to be detected. For instance, any “killer” defects that may cause yield loss can be indicated as a DOI. In some other cases, a defect may be a nuisance (also referred to as “false alarm” defect) which can be disregarded because it has no effect on the functionality of the completed device and does not impact yield.

The term “defect candidate” used in this specification should be expansively construed to cover a suspected defect location on the specimen which is detected to have relatively high probability of being a defect of interest (DOI). Therefore, a DOI candidate, upon being reviewed/tested, may actually be a DOI, or, in some other cases, it may be nuisances, or random noise that can be caused by different variations (e.g., process variation, color variation, mechanical and electrical variations, etc.) during inspection.

The term “design data” used in the specification should be expansively construed to cover any data indicative of hierarchical physical design (layout) of a specimen. Design data can be provided by a respective designer and/or can be derived from the physical design (e.g., through complex simulation, simple geometric and Boolean operations, etc.). Design data can be provided in different formats as, by way of non-limiting examples, GDSII format, OASIS format, etc. Design data can be presented in vector format, grayscale intensity image format, or otherwise.

The term “image(s)” or “image data” used in the specification should be expansively construed to cover any original images/frames of the specimen captured by an examination tool during the fabrication process, derivatives of the captured images/frames obtained by various pre-processing stages, and/or computer-generated synthetic images (in some cases based on design data). Depending on the specific way of scanning (e.g., one-dimensional scan such as line scanning, two-dimensional scan in both x and y directions, or dot scanning at specific spots, etc.), image data can be represented in different formats, such as, e.g., as a gray level profile, a two-dimensional image, or discrete pixels, etc. It is to be noted that in some cases the image data referred to herein can include, in addition to images (e.g., captured images, processed images, etc.), numeric data associated with the images (e.g., metadata, hand-crafted attributes, etc.). It is further noted that images or image data can include data related to a processing step/layer of interest, or a plurality of processing steps/layers of a specimen.

It is appreciated that, unless specifically stated otherwise, certain features of the presently disclosed subject matter, which are described in the context of separate embodiments, can also be provided in combination in a single embodiment. Conversely, various features of the presently disclosed subject matter, which are described in the context of a single embodiment, can also be provided separately or in any suitable sub-combination. In the present detailed description, numerous specific details are set forth in order to provide a thorough understanding of the methods and apparatus.

In embodiments of the presently disclosed subject matter, fewer, more, and/or different stages than those shown in the methods of FIGS. 2 and 3 may be executed. In embodiments of the presently disclosed subject matter, one or more stages illustrated in the methods of FIGS. 2 and 3 may be executed in a different order, and/or one or more groups of stages may be executed simultaneously.

It will also be understood that the system according to the present disclosure may be, at least partly, implemented on a suitably programmed computer. Likewise, the present disclosure contemplates a computer program being readable by a computer for executing the method of the present disclosure. The present disclosure further contemplates a non-transitory computer-readable memory tangibly embodying a program of instructions executable by the computer for executing the method of the present disclosure.

The present disclosure is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the presently disclosed subject matter.

Those skilled in the art will readily appreciate that various modifications and changes can be applied to the embodiments of the present disclosure as hereinbefore described without departing from its scope, defined in and by the appended claims.

1. A computerized system of automatic creation of an imaging recipe of an electron beam tool, the system comprising a processing circuitry configured to:
obtain, as input, material properties and structural properties of a semiconductor specimen of interest (SOI);
perform, based on the input, a first simulation representative of interaction between irradiated electrons of a primary beam of the electron beam tool and the SOI at a plurality of primary beam configurations characterized by different values of a set of primary beam parameters, to obtain, for each primary beam configuration, a map representative of distribution of escaped electrons in terms of polar angle and escape energy;
perform, based on the map, a second simulation representative of collection and detection of the escaped electrons at different tool imaging configurations characterized by different values of a set of tool imaging parameters, to obtain a signal profile of a measurement of interest (MOI) on the SOI at each tool imaging configuration; and
create an imaging recipe for the electron beam tool, comprising the set of primary beam parameters and the set of tool imaging parameters configured with values that result in an optimal contrast of the MOI in the signal profile.

2. The computerized system according to claim 1, wherein the material properties comprise one or more of: composition, density, and stoichiometric formula of materials constituting the specimen, and wherein the structural properties comprise one or more of: layer layout, thickness, and geometric dimensions of structural features on each layer.

3. The computerized system according to claim 1, wherein the set of primary beam parameters comprises one or more of: landing energy, beam resolution, current amplitude, current density, electron source, and numerical aperture (NA) of the electron beam tool.

4. The computerized system according to claim 1, wherein the set of tool imaging parameters comprises one or more of: detector angle, detector gain, defector offset, electrostatic field, voltage, mechanical configuration, dwell time, scanning speed, pixel size, and energy filter of the electron beam tool, and the signal profile is represented in a multi-dimensional parameter space.

5. The computerized system according to claim 1, wherein the processing circuitry is configured to perform the second simulation by simulating a signal detected by a given detector based on a correlation between detector gain, energy and current of incoming electrons of the given detector.

6. The computerized system according to claim 1, wherein the imaging recipe is a wafer-less recipe which is created without acquiring an actual SOI, thereby enabling improved time-to-recipe.

7. The computerized system according to claim 1, wherein the SOI is Vertical NAND (V-NAND), the MOI represents an overlay measurement between two consecutive tiers, and wherein the imaging recipe comprises at least a landing energy configured within a selected range and a side detector positioned at a polar angle within a selected range.

8. The computerized system according to claim 7, wherein the imaging recipe further comprises the side detector configured with a selected detector gain, and at least one energy filter configured to filter out escaped electrons with unwanted energy levels.

9. The computerized system according to claim 1, wherein simulation data of the first simulation and the second simulation is usable to design a new e-beam tool with tool parameters configured with selected values proven to result in an optimal contrast of the MOI.

10. The computerized system according to claim 1, wherein simulation data of the first simulation and the second simulation is usable for providing feedback to manufacturers with respect to optimizing material properties and/or structural properties of future specimens of interests (SOIs) to be manufactured for enhancing an electron beam examination process.

11. The computerized system according to claim 1, wherein the electron beam tool is one of: a defect inspection tool, a defect review tool, or a metrology tool.

12. A computerized method of automatic creation of an imaging recipe of an electron beam tool, the method comprising:
obtaining, as input, material properties and structural properties of a semiconductor specimen of interest (SOI);
performing, based on the input, a first simulation representative of interaction between irradiated electrons of a primary beam of the electron beam tool and the SOI at a plurality of primary beam configurations characterized by different values of a set of primary beam parameters, to obtain, for each primary beam configuration, a map representative of distribution of escaped electrons in terms of polar angle and escape energy;
performing, based on the map, a second simulation representative of collection and detection of the escaped electrons at different tool imaging configurations characterized by different values of a set of tool imaging parameters, to obtain a signal profile of a measurement of interest (MOI) on the SOI at each tool imaging configuration; and
creating an imaging recipe for the electron beam tool, comprising the set of primary beam parameters and the set of tool imaging parameters configured with values that result in an optimal contrast of the MOI in the signal profile.

13. The computerized method according to claim 12, wherein the material properties comprise one or more of: composition, density, and stoichiometric formula of materials constituting the specimen, and wherein the structural properties comprise one or more of: layer layout, thickness, and geometric dimensions of structural features on each layer.

14. The computerized method according to claim 12, wherein the set of primary beam parameters comprises one or more of: landing energy, beam resolution, current amplitude, current density, electron source, and numerical aperture (NA) of the electron beam tool.

15. The computerized method according to claim 12, wherein the set of tool imaging parameters comprises one or more of: detector angle, detector gain, defector offset, electrostatic field, voltage, mechanical configuration, dwell time, scanning speed, pixel size, and energy filter of the electron beam tool, and the signal profile is represented in a multi-dimensional parameter space.

16. The computerized method according to claim 12, wherein the performing the second simulation comprises simulating a signal detected by a given detector based on a correlation between detector gain, energy, and current of incoming electrons of the given detector.

17. The computerized method according to claim 12, wherein the imaging recipe is a wafer-less recipe which is created without acquiring an actual SOI, thereby enabling improved time-to-recipe.

18. The computerized method according to claim 12, wherein the SOI is Vertical NAND (V-NAND), the MOI represents an overlay measurement between two consecutive layers, and wherein the imaging recipe comprises at least a landing energy configured within a selected range and a side detector positioned at a polar angle within a selected range.

19. The computerized method according to claim 18, wherein the imaging recipe further comprises the side detector configured with a selected detector gain, and at least one energy filter configured to filter out escaped electrons with unwanted energy levels.

20. A non-transitory computer readable storage medium tangibly embodying a program of instructions that, when executed by a computer, cause the computer to perform a method of automatic creation of an imaging recipe of an electron beam tool, the method comprising:
obtaining, as input, material properties and structural properties of a semiconductor specimen of interest (SOI);
performing, based on the input, a first simulation representative of interaction between irradiated electrons of a primary beam of the electron beam tool and the SOI at a plurality of primary beam configurations characterized by different values of a set of primary beam parameters, to obtain, for each primary beam configuration, a map representative of distribution of escaped electrons in terms of polar angle and escape energy;
performing, based on the map, a second simulation representative of collection and detection of the escaped electrons at different tool imaging configurations characterized by different values of a set of tool imaging parameters, to obtain a signal profile of a measurement of interest (MOI) on the SOI at each tool imaging configuration; and
creating an imaging recipe for the electron beam tool, comprising the set of primary beam parameters and the set of tool imaging parameters configured with values that result in an optimal contrast of the MOI in the signal profile.
